(19) United States
(12) Patent Application Publication
(10) Pub. No.: US 2011/0267751 A1
(43) Pub. Date: Nov. 3, 2011

(54) DISPLAY DEVICE AND FRAME MOUNTABLE ON THE DISPLAY DEVICE

(75) Inventors: Masanori Shimo, Osaka-shi (JP); Takafumi Hara, Osaka-shi (JP); Eriko Wakabayashi, Osaka-shi (JP); Saori Nambo, Osaka-shi (JP)

(73) Assignee: SHARP KABUSHIKI KAISHA, Osaka-shi, Osaka (JP)

(21) Appl. No.: 13/144,965

(22) PCT Filed: Oct. 30, 2009
(86) PCT No.: PCT/JP2009/068701

§ 371 Date: Jul. 18, 2011

(30) Foreign Application Priority Data
Jan. 23, 2009 (JP) 2009-012603

(51) Int. Cl. H05K 7/00

(52) U.S. Cl. 361/679.01

(57) ABSTRACT

In a display device provided by the present invention, among a plurality of sides forming a frame 30, one pair of sides facing each other respectively have protrusions 52 and 62 and clearance adjusting members 54 and 64, for adjusting a clearance between the protrusions 52 and 62 and a display panel 10 located on an inner-side panel receiving portion, provided as at least partially extending toward the inner-side panel receiving portion. An extending portion, extending toward the inner-side panel receiving portion, of one of the clearance adjusting members, i.e., the clearance adjusting member 54, and an extending portion, extending toward the inner-side panel receiving portion, of the other clearance adjusting member 64, have different thicknesses from each other in respective extending directions thereof.

### TECHNICAL FIELD

The present invention relates to a display device including a display panel and a frame mountable on such a display device.

### BACKGROUND ART

Recently, liquid crystal display devices including a liquid crystal display panel having a rectangular shape are in wide use as display devices (displays) for TVs, personal computers and the like.

This type of display device includes a bezel, which is a frame member (front frame), on the front side of the display panel. On the rear side of the panel, a frame (e.g., a resin frame is also referred to as a “P chassis (plastic chassis)”) is provided between the panel and a backlight device, which is a light source for the panel. The bezel and the frame are each formed to have a frame-like shape surrounding a rectangular display area (active area) located in a central area of the liquid crystal display panel, and hold a rectangular-like peripheral portion of the panel from the front side and the rear side of the display panel.

As one form of the frame mentioned above, a frame as described in Patent Document 1 is known, for example. In an inner peripheral portion of a surface of the frame facing the liquid crystal display panel, a panel receiving area is formed. In addition, on at least one side portion of the frame, a protrusion formed of a rib or a step and contactable with a side surface of the liquid crystal display panel placed on the panel receiving area (inner peripheral portion) is formed outer to the panel receiving area.

When a frame of such a form is used, the protrusion is usable for positioning the liquid crystal display panel in order to place the liquid crystal display panel on the panel receiving area. More specifically, by bringing the side surface of the panel into contact with the protrusion, the position of the liquid crystal display panel with respect to the frame is determined. In the state of being so positioned, the liquid crystal display panel is covered with the bezel, and thus the panel can be held between the frame and the bezel at this position (i.e., the preset correct position). Typically, the position of the protrusion is predetermined such that in the state where the side surface of the panel is in contact with the protrusion (i.e., in the state where the panel is positioned), the liquid crystal display panel can be at the center of the frame without being unevenly closer to any of the sides of the frame.

### CITATION LIST

### Patent Document

Patent Document 1: Japanese Patent Laid-Open Publication No. 8-179283

### SUMMARY OF THE INVENTION

### Technical Problem

Recently, as the liquid crystal display panels have been increased in size, the frames have also been increased in size. It is not efficient to mold such a large frame as one component. Therefore, a plurality of frame components having a shape obtainable by dividing a frame of a frame-like shape into two or more are molded, and a frame is formed by connecting such a plurality of frame components to each other when constructing a liquid crystal display device. In this case, it is more efficient that the number of types of frame components used to construct one frame is smaller. Accordingly, frame components which are shaped such that a frame constructed by connecting the frame components to each other realizes a point symmetry with respect to the center thereof are used. Typically, in the case of a rectangular-like frame, one type of generally C-shaped frame components realizing a point symmetry when the frame is constructed, or two types of L-shaped frame components (or one type of L-shaped frame components if one of the types, when being put upside down, has the same shape as the other type) realizing a point symmetry when the frame is constructed, are used.

When such frame components realizing a point symmetry are used, it is difficult to form positioning means for positioning the liquid crystal display panel, such as the above-described protrusion. When a protrusion is formed in one of the frame components realizing a point symmetry, the constructed frame has the same protrusion at a position having a point symmetry with respect to the first protrusion. These two protrusions restrict the size of the panel receiving area defined therebetween.

This will be described more specifically. When protrusions are formed such that the panel can be located at the center of the frame in the state where a side surface of the panel contacts either one of the protrusions, the other protrusion located to have a point symmetry with respect to the one protrusion exists at a position contactable with the opposite side surface of the panel. This means that the size of the panel receiving area between the protrusions is the same as the size of the liquid crystal display panel between the two side surfaces, and that there is no clearance at all for placing the liquid crystal display panel on the panel receiving area. Such a state makes it significantly difficult to place the liquid crystal display panel on the panel receiving area because the two protrusions having a point symmetry act as a barrier.

In order to provide the protrusions at such positions that a clearance can be made with certainty, the distance between the protrusions having a point symmetry, namely, the size of the panel receiving area between the protrusions, needs to be excessively larger than the size of the liquid crystal display panel between the side surfaces. This means that in the state where one side surface of the liquid crystal display panel contacts one of the protrusions, the panel cannot be at the center of the frame. This makes it difficult to position the liquid crystal display panel on the frame.

The present invention made in light of these points has a main object of providing a liquid crystal, or any other type of, display device including means capable of positioning a display panel correctly even when a plurality of frame components realizing a point symmetry as described above are used. Another object of the present invention is to provide a frame, for a display device, including such means.

### Solution to the Problem

In order to achieve the above-described objects, a display device provided by the present invention includes a display panel having a rectangular shape; a frame of a frame-like shape located on a rear side of the display panel; and a bezel of a frame-like shape located on a front side of the display panel. The panel is held between the frame and the bezel. A surface of the frame facing the panel has an inner-side panel receiving portion on which at least a part of a peripheral portion of the panel is located, and a protrusion formed outer to the inner-side panel receiving portion. Among a plurality of sides forming the frame, either one pair of sides facing each other each have the protrusion formed thereon. A clearance adjusting member for adjusting a clearance between the protrusion and the display panel located on the inner-side panel receiving portion is provided (on each of the one pair of sides) as at least partially extending toward the inner-side panel receiving portion. The clearance adjusting members of the one pair of sides are shaped differently from each other such that an extending portion, extending toward the inner-side panel receiving portion, of the clearance adjusting member provided on one of the one pair of sides, and an extending portion, extending toward the inner-side panel receiving portion, of the clearance adjusting member provided on the other of the one pair of sides, have different thicknesses from each other in respective extending directions thereof.

In the display device according to the present invention, the frame included in the display device includes clearance adjusting members. Owing to this, the size of the clearance obtained between each protrusion and the display panel is adjusted, and the size of the panel receiving area between the protrusions provided with the clearance adjusting members can be made approximate to the size of the display panel between the side surfaces thereof. Therefore, the display panel is located at a position very close to the center of the frame, and so the positioning of the display panel can be performed in a preferable manner. It is preferable to determine either one of the clearance adjusting members as a positioning member because the display panel can be located at the center of the frame by bringing the display panel into contact with the member so determined.

The clearance adjusting members respectively provided on the pair of sides have different thicknesses from each other in the extending directions thereof. Owing to this, when, for example, the display panel is located on the frame while being in contact with the clearance adjusting member capable of acting as the positioning member (typically, the thicker clearance adjusting member), a slight gap is made between the other (typically, thinner) clearance adjusting member (the side surface thereof) and the corresponding side surface of the liquid crystal panel. Namely, such a gap can be a clearance, and so the display panel can be easily located on the frame without allowing the display panel to interfere with the protrusion or the clearance adjusting member.

Accordingly, according to the present invention, a preferable display device which allows a display panel to be located easily while positioning the display panel with respect to a frame in a preferable manner is provided.

In one preferable embodiment of the display device disclosed herein, the clearance adjusting member provided on one of the one pair of sides is formed to be thicker than the clearance adjusting member provided on the other of the one pair of sides.

In the display device having such a structure, the overall shape of the pair of clearance adjusting members is preferably parallelepiped or cylindrical. By forming one of such clearance adjusting members to be entirely thicker than the other, the thicknesses of the clearance adjusting members can be easily made different from each other in the extending directions thereof.

In another preferable embodiment of the display device disclosed herein, among the clearance adjusting member provided on one of the one pair of sides and the clearance adjusting member provided on the other of the one pair of sides which have different thicknesses from each other, at least one clearance adjusting member is colored or marked so that the clearance adjusting members are visually distinguishable from each other.

With the display device having such a structure, the clearance adjusting members can be visually distinguishable from each other. Owing to this, for example, the clearance adjusting member set as the positioning member can be easily distinguished, and so the positioning of the liquid crystal panel with respect to the frame can be performed efficiently.

In still another preferable embodiment of the display device disclosed herein, the clearance adjusting members are formed of an elastic material.

In the display device having such a structure, the clearance adjusting members are formed of an elastic material such as, for example, rubber, elastomer or the like. This provides the following effects. For locating the display panel on the frame while bringing the display panel into contact with the clearance adjusting member, the display panel is pressed to one of the clearance adjusting members to compress the member to reduce the thickness of the member in the extending direction. Owing to this, the gap (clearance) formed between the other clearance adjusting member and the corresponding side surface of the display panel can be increased. This makes it easy to locate the display panel on the frame.

Once the display panel is located, the clearance adjusting member compressed above can be recovered. After the clearance adjusting member is recovered, the display panel can be located at the correct position on the frame.

In addition, the clearance adjusting member can act as a cushioning member. For example, while the display panel is being located on the frame, while the constructed display device is being transported, etc., the impact or strong vibration given to the display panel is alleviated and the contact of the display panel with the frame is significantly reduced. Owing to this, the display panel can be prevented from being damaged due to a contact with the frame.

In still another preferable embodiment of the display device disclosed herein, the frame is formed of a plurality of frame components connected to each other. The plurality of frame components are shaped such that the frame formed of the plurality of frame components connected to each other realizes a point symmetry with respect to a central point thereof.

With the display device having such a structure, even when a frame formed of a plurality of frame components and shaped to realize a point symmetry is used, the display panel can be easily located while being positioned with respect to the frame in a preferable manner.

As another aspect, the present invention provides a frame included in the display device disclosed herein. Such a frame is a frame of a frame-like shape for a display device including a display panel having a rectangular shape, the frame being located on a rear side of the display panel. A surface of the frame which is to face the panel when the display device is constructed has an inner-side panel receiving portion on which at least a part of a peripheral portion of the panel is to be located, and a protrusion formed outer to the inner-side panel receiving portion. Among a plurality of sides forming the frame, either one pair of sides facing each other each have the protrusion formed thereon. A clearance adjusting member for adjusting a clearance between the protrusion and the display panel to be located on the inner-side panel receiving portion is provided (on each of the one pair of sides) as at least partially extending toward the inner-side panel receiving portion. The clearance adjusting members of the one pair of sides are shaped differently from each other such that an extending portion, extending toward the inner-side panel receiving portion, of the clearance adjusting member provided on one of the one pair of sides, and an extending portion, extending toward the inner-side panel receiving portion, of the clearance adjusting member provided on the other of the one pair of sides, have different thicknesses from each other in respective extending directions thereof.

In the frame for a display device according to the present invention, the pair of clearance adjusting members are provided. Therefore, by using such a frame, a preferable display device which allows the display panel to be located easily while positioning the display panel with respect to a frame in a preferable manner is provided.

In one preferable embodiment of the frame for a display device disclosed herein, the clearance adjusting member provided on one of the one pair of sides is formed to be thicker than the clearance adjusting member provided on the other of the one pair of sides.

In the frame for a display device having such a structure, one of the clearance adjusting members is formed to be thicker than the other clearance adjusting member. Therefore, by using such a frame, a display device which easily allows the thicknesses of the clearance adjusting members to be different from each other in the extending directions thereof is provided.

In another preferable embodiment of the frame for a display device disclosed herein, among the clearance adjusting member provided on one of the one pair of sides and the clearance adjusting member provided on the other of the one pair of sides which have different thicknesses from each other, at least one clearance adjusting member is colored or marked so that the clearance adjusting members are visually distinguishable from each other.

In the frame for a display device having such a structure, the clearance adjusting members are visually distinguishable from each other. Therefore, by using such a frame, a display device which allows, for example, the clearance adjusting member acting as the positioning member to be easily distinguished and performs the positioning of the liquid crystal panel efficiently is provided.

In still another preferable embodiment of the frame for a display device disclosed herein, the clearance adjusting members are formed of an elastic material.

By using the frame for a display device having such a structure, a display device which allows the display panel to be easily located on the frame, allows the display panel to be located at the correct position on the frame, and also can prevent the display panel from being damaged due to a contact with the frame is provided.

In still another preferable embodiment of the frame for a display device disclosed herein, the frame is formed of a plurality of frame components connected to each other. The plurality of frame components are shaped such that the frame formed of the plurality of frame components connected to each other realizes a point symmetry with respect to a central point thereof.

Even when the frame for a display device having such a structure is used, a display device which allows the display panel to be easily located while positioning the display panel with respect to the frame in a preferable manner is provided.

### BRIEF DESCRIPTION OF THE DRAWINGS

FIG. 1 is an exploded perspective view schematically showing a structure of a liquid crystal display device according to an embodiment of the present invention.

FIG. 2 is a cross-sectional view schematically showing the structure of the liquid crystal display device according to an embodiment of the present invention.

FIG. 3 is a perspective view schematically showing the entirety of a frame included in the liquid crystal display device according to an embodiment of the present invention.

FIG. 4 is an exploded perspective view schematically showing the frame included in the liquid crystal display device according to an embodiment of the present invention.

FIG. 5 is an enlarged view of the V part in FIG. 3, and is a schematic view showing a state where one of a pair of clearance adjusting members is located in the frame.

FIG. 6 is an enlarged view of the VI part in FIG. 3, and is a schematic view showing a state where the other of the pair of clearance adjusting members is located in the frame.

FIG. 7 is a perspective view showing a state where a liquid crystal panel is being located on the frame including the clearance adjusting members.

FIG. 8 is a plan view showing an important part of the frame in the state where the liquid crystal panel is located on the frame.

### DESCRIPTION OF EMBODIMENTS

Hereinafter, some preferable embodiments of the present invention will be described with reference to the drawings. Elements which are other than the elements specifically described in this specification (e.g., the structure of a frame) but are necessary to carry out the present invention (e.g., the structure and production method of the liquid crystal panel, the structure of a light source included in the liquid crystal display device, the electrical circuit used by the driving system of the light source, etc.) may be understood as being the matter of design choice determined by a person of ordinary skill in the art based on the conventional art. The present invention can be carried out based on the contents disclosed in this specification and the technological common knowledge in the art.

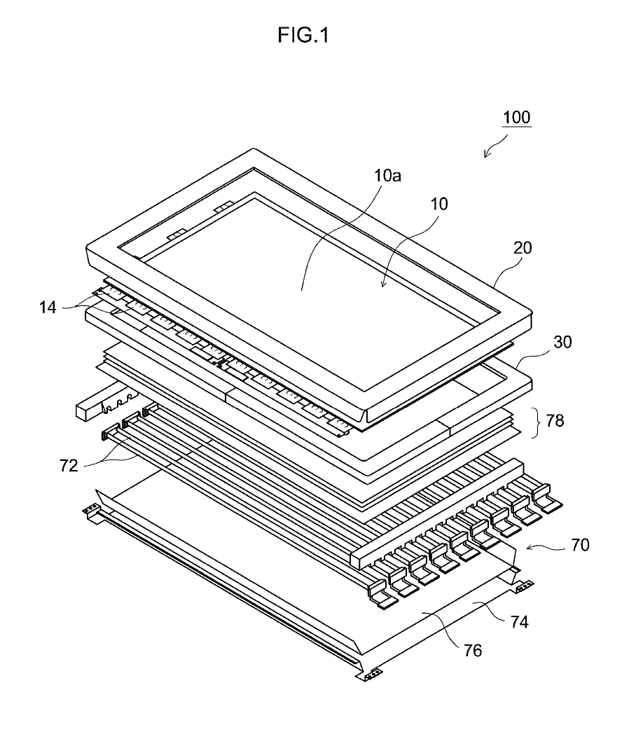

Hereinafter, with reference to FIG. 1 through FIG. 8, a liquid crystal display device 100 of an active matrix system (TFT type) including a liquid crystal panel 10 as a display panel will be described as an example of display device according to one preferable embodiment of the present invention. In the figures referred to below, members or portions having the same functions may bear the same reference characters and descriptions thereof may not be repeated or may be simplified. In the figures, the relative sizes (length, width, thickness, etc.) do not necessarily reflect the actual relative sizes accurately. In the following description, the “front surface” and “front side” mean the side of the liquid crystal display device 100 facing the viewer (i.e., the liquid crystal panel side), and the “rear surface”, “rear side” and “back side” mean the side of the liquid crystal display device 100 not facing the viewer (i.e., the backlight device side).

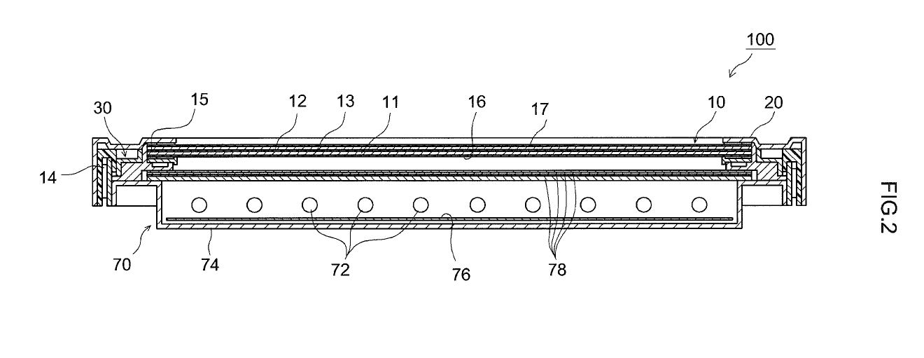

With reference to FIG. 1 and FIG. 2, a structure of the liquid crystal display device 100 will be described. As shown in FIG. 1, the liquid crystal display device 100 includes the liquid crystal panel 10 and a backlight device 70, which is an external light source located on the rear side of the liquid crystal panel 10 (lower side in FIG. 1). The liquid crystal panel 10 and the backlight device 70 are integrally held by being assembled by a bezel 20 and the like.

As shown in FIG. 1 and FIG. 2, the liquid crystal panel 10 has a generally rectangular overall shape. In a central area of the liquid crystal panel 10, a display area 10a including pixels for displaying an image is formed. The liquid crystal panel 10 has a sandwich structure including a pair of light-transmissive glass substrates 11 and 12 facing each other and a liquid crystal layer 13 confined therebetween. As each of the substrates 11 and 12, a substrate cut from a large mother member called “mother glass” during a production process thereof is used. Among the pair of substrates 11 and 12, the substrate on the front side is a color filter substrate (CF substrate) 12, and the substrate on the rear side is an array substrate 11. On a peripheral portion of each of the substrates 11 and 12 (the peripheral portion of the liquid crystal panel 10), a sealant 15 is provided so as to surround the periphery of the pixel area 10a. The sealant 15 confines the liquid crystal layer 13. The liquid crystal layer 13 is formed of a liquid crystal material containing liquid crystal molecules. The orientation of the liquid crystal molecules in such a liquid crystal material is controlled by an electric field applied between the substrates 11 and 12, and thus the optical characteristics of the liquid crystal material are changed. In the liquid crystal layer 13, a spacer (not shown) for providing a thickness (gap) of the layer 13 is located, typically at a plurality of positions. On surfaces of the substrates 11 and 12 facing each other (inner surfaces), alignment films (not shown) for determining the orientation of the liquid crystal molecules are respectively formed. On surfaces of the substrates 11 and 12 not facing each other (outer surfaces), polarizer plates 16 and 17 are respectively bonded.

In the liquid crystal panel 10 disclosed herein, the pixels (more precisely, sub pixels) for displaying an image are arranged in the array substrate 11 on the front side thereof (side facing the liquid crystal layer 13). Also on the front side of the array substrate 11, a plurality of source lines and a plurality of gate lines (not shown) for driving each of the pixels (sub pixels) are formed in a grid pattern. In each of the grid areas surrounded by these lines, a (sub) pixel electrode and a thin film transistor (TFT) acting as a switching element are provided. Typically, the pixel electrode is formed of ITO (Indium Tin Oxide), which is a transparent conductive material. The pixel electrodes are supplied with a voltage in accordance with the image at a prescribed timing via the source lines and the thin film transistors.

In the CF substrate 12, a color filter of one of the colors of R (red), G (green) and B (blue) faces each one of the pixel electrodes provided in the array substrate 11. The CF substrate 12 also includes a black matrix for partitioning the color filters of these colors from each other, and a common electrode (transparent electrode) formed uniformly on a surface of the color filters and the black matrix.

As shown in FIG. 1, the source lines and the gate lines are typically connected to external driving circuits (driver ICs) 14, provided in the peripheral portion of the liquid crystal panel 10, which can supply image signals and the like.

The structure of the pixels and the wiring of the electrodes described above may be substantially the same as those for producing a conventional liquid crystal panel and do not characterize the present invention, and so will not be described in more detail.

As shown in FIG. 1 and FIG. 2, the backlight device 70 located on the rear side (back side) of the liquid crystal panel 10 includes a plurality of linear light sources (e.g., fluorescent tubes, typically, cold-cathode fluorescent tubes) 72 and a case (chassis) 74 for accommodating the light sources 72. The case 74 has a shape of box opened toward the front side. The light sources 72 are arranged parallel to each other in the case 74. A reflective member 76 for reflecting light from the light sources 72 toward the viewer's side efficiently is provided between the case 74 and the light sources 72.

In the opening of the case 74, a plurality of sheet-like optical members 78 are stacked and located so as to cover the opening. The optical members 78 are, for example, a diffuser, a diffusion sheet, a lens sheet and a luminance increasing sheet which are located sequentially in this order from the backlight device 70 side toward the liquid crystal panel 10 side. The optical members 78 are not limited to being this combination of elements or being located in this order. The case 74 is further provided with a frame 30 having a generally frame-like shape in order to hold the optical members 78 in the state where the optical members 78 are fit into the case 74. On the back side of the case 74, an inverter circuit board (not shown) on which an inverter circuit is mounted and an inverter transducer (not shown) as a booster circuit for supplying power to each of the light sources 72 are provided, but these elements do not characterize the present invention and so will not be described.

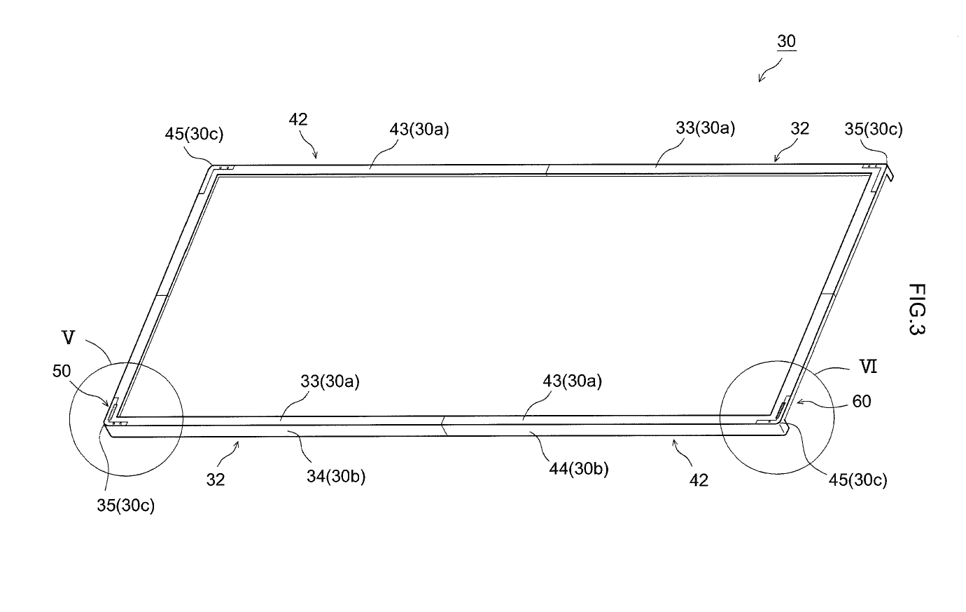

As described above, the optical members 78 are located on the front side of the backlight device 70. The frame 30 having an opening in an area corresponding to the display area 10a of the liquid crystal panel 10 is mounted on the front side of the optical members 78 so that the optical members 78 are held by the frame 30 and the backlight device 70. On the front side of the frame 30, the liquid crystal panel 10 is placed on a front portion 30a (see FIG. 3) of the frame 30. Also on the front side of the liquid crystal panel 10, the bezel 20 of a frame-like shape is mounted. The liquid crystal panel 10 is typically located between the bezel 20 and the frame 30 and is typically held therebetween via, for example, a cushioning member (not shown) of an elastic material, for example, rubber, elastomer or the like.

The liquid crystal display device 100 of the above-described structure including the liquid crystal panel 10, the backlight device 70 and the like controls the liquid crystal molecules in the liquid crystal layer 13 by applying a controlled voltage to the array substrate 11 and the CF substrate 12, and passes or blocks light from the backlight device 70 by the liquid crystal panel 10. The liquid crystal display device 100 displays a desired image in the display area 10a of the liquid crystal panel 10 while controlling the luminance or the like of the backlight device 70.

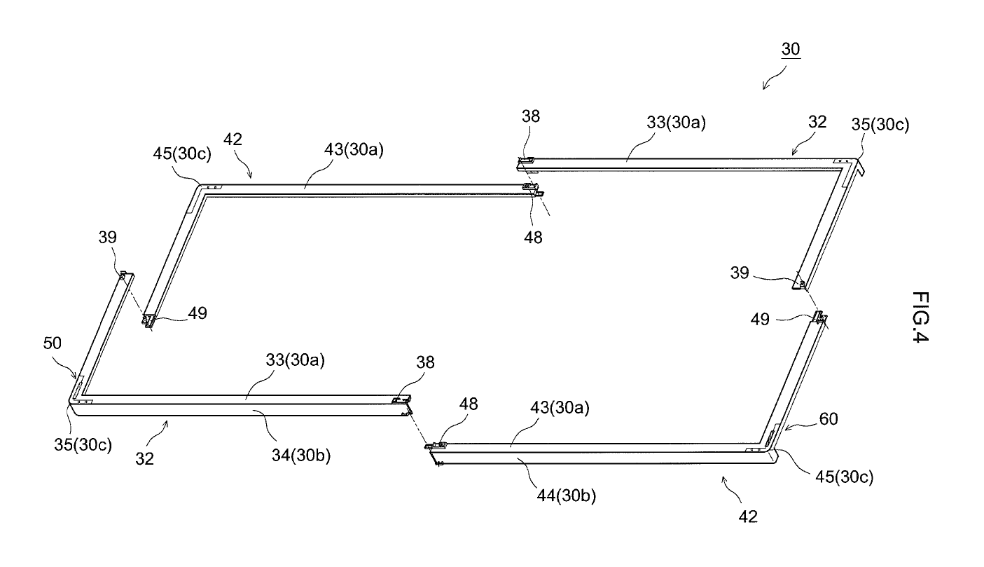

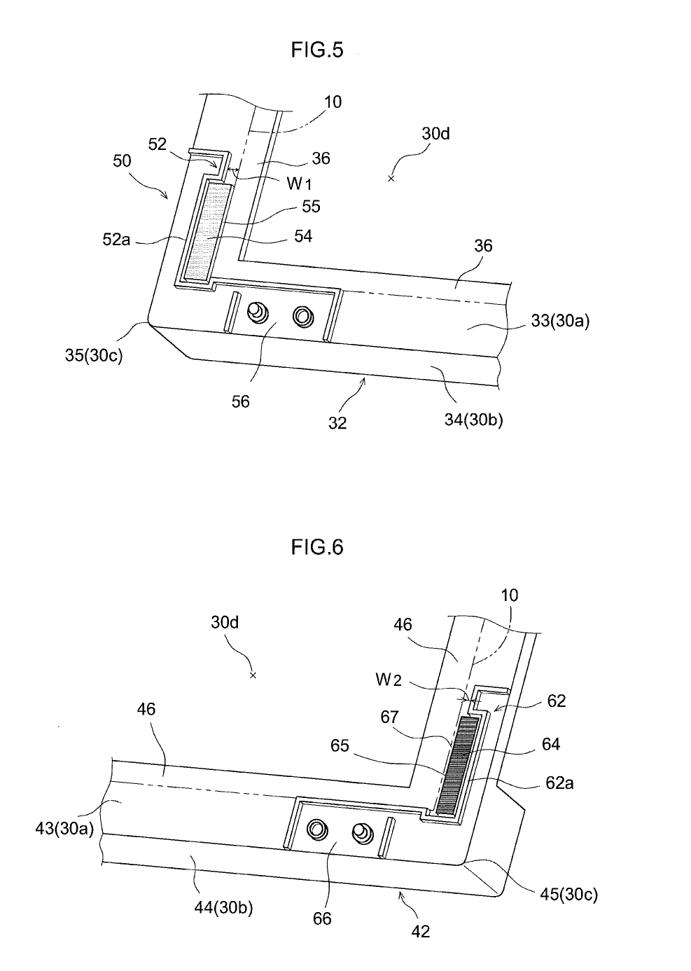

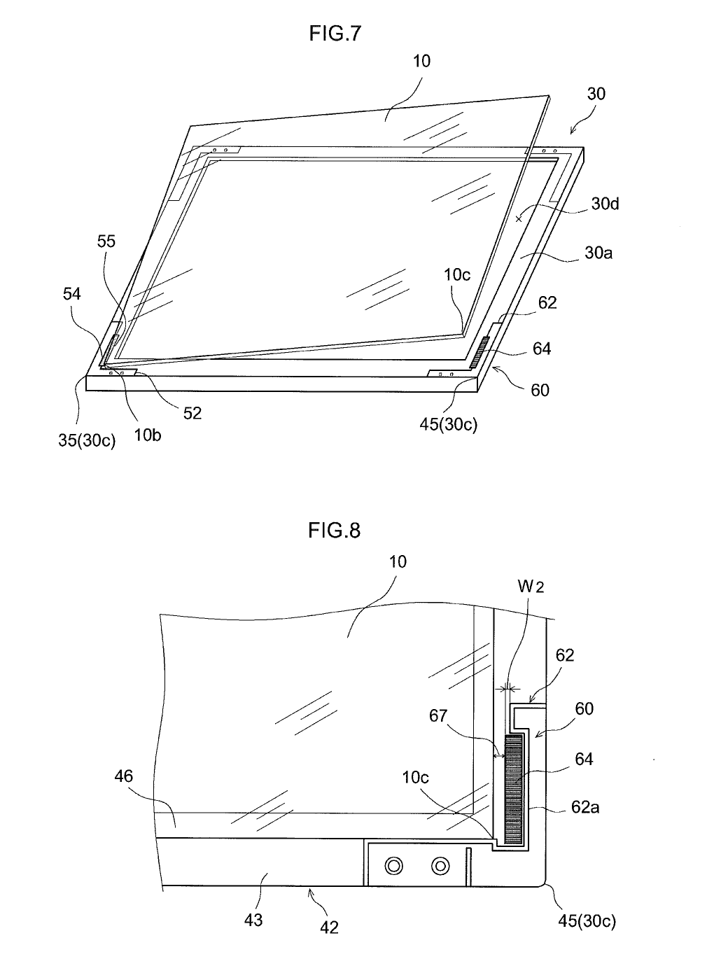

Now, with reference to FIG. 3 through FIG. 8, the structure of the frame 30 of the liquid crystal display device 100 in this embodiment will be described in more detail. FIG. 3 is a perspective view schematically showing the entirety of the frame 30 included in the liquid crystal display device 100. FIG. 4 is an exploded perspective view schematically showing the frame 30 included in the liquid crystal display device 100. FIG. 5 is an enlarged view of the V part in FIG. 3, and is a schematic view showing a state where one of a pair of clearance adjusting members 54 and 64, i.e., the clearance adjusting member 54, is located in the frame 30. FIG. 6 is an enlarged view of the VI part in FIG. 3, and is a schematic view showing a state where the other of the pair of clearance adjusting members 54 and 64, i.e., the clearance adjusting member 64, is located in the frame 30. FIG. 7 is a perspective view showing a state where the liquid crystal panel 10 is being located on the frame 30 including the clearance adjusting members 54 and 64. FIG. 8 is a plan view showing an important part of the frame 30 (frame corner portion 45 and the vicinity thereof) in the state where the liquid crystal panel 10 is located on the frame 30.

As shown in FIG. 3, the frame 30 in this embodiment is located on the rear side of the liquid crystal panel 10. The frame 30 is a component which has a frame-like shape as seen in a plan view and is formed so as to surround the rectangular display area 10a located in a central area of the liquid crystal panel 10. The frame 30 is structured to hold the peripheral portion around the display area 10a (rectangular-like peripheral portion) together with the bezel 20, which is located on the front side of the liquid crystal panel 10 so as to surround the rectangular display area 10a. The frame 30 has the front portion 30a which contacts a rear surface of the panel 10 when the liquid crystal panel 10 is mounted thereon and a side portion 30b extending from the front portion 30a perpendicularly thereto to cover side surfaces of longer sides of the rectangular-like peripheral portion (i.e., longer sides among the four sides surrounding the rectangular display area 10a). The frame 30 having such an overall structure is formed of four frame components 32 and 42, each of which has a shape obtainable by dividing the rectangular-like peripheral portion into four. Namely, the frame 30 of the frame-like shape described above is formed by coupling the four frame components 32 and 42 to each other.

As shown in FIG. 4, each of the frame components 32 and 42 has a shape obtainable by dividing the frame 30 into four at generally the central point of each of the four sides of the rectangular-like frame 30, and thus has an L-shape including each one corner 30c of the four corners of the frame 30 as seen in a plan view. The frame components 32 and 42 respectively include front frame portions 33 and 43 which form the front portion 30a of the frame 30, side frame portions 34 and 44 which form the side portion 30b of the frame 30, and frame corner portions 35 and 45 each of which forms the corner 30c of the frame 30. The front frame portions 33 and 43 and the side frame portions 34 and 44 may have a plurality of openings (e.g., rectangular openings) arranged at a prescribed interval in order to, for example, improve the efficiency of releasing the heat generated when the liquid crystal panel 10 is driven and/or to reduce the cost of the material, although such openings are not shown.

As described above, the frame component 32 has an L-shape as seen in a plan view. The frame component 32 includes a longer side of the four sides of the frame 30 (precisely, half of the longer side) and a shorter side of the four sides (precisely, half of the shorter side). The frame corner portion 35, at which such a longer side portion and such a shorter side portion cross each other perpendicularly, forms one of the four corners 30c of the frame 30. In the frame corner portion 35, the front frame portion 33 has a panel locating structure 50 formed thereon, on which a corner of the panel 10 is to be located when the liquid crystal panel 10 is mounted. When the frame 30 is constructed, the panel locating structure 50 faces a panel locating structure 60 described later in the direction of the longer side. Two ends 38 and 39 of the frame component 32 are coupling portions 38 and 39 including coupling structures to be coupled with ends 48 and 49 of the frame component 42, respectively.

Like the frame component 32, the frame component 42 has an L-shape as seen in a plan view. The frame component 42 includes a longer side of the four sides of the frame 30 (precisely, half of the longer side) and a shorter side of the four sides (precisely, half of the shorter side). The frame corner portion 45, at which such a longer side portion and such a shorter side portion cross each other perpendicularly, forms one of the four corners 30c of the frame 30. In the frame corner portion 45, the front frame portion 43 has a panel locating structure 60 formed thereon, on which a corner of the panel 10 is to be located when the liquid crystal panel 10 is mounted. When the frame 30 is constructed, the panel locating structure 60 faces the panel locating structure 50 in the direction of the longer side. The two ends 48 and 49 of the frame component 42 are coupling portions 48 and 49 including coupling structures to be coupled with the ends 38 and 39 of the frame component 32, respectively. The coupling structures are not limited to having a form shown in FIG. 4, and there is no limitation on the form of the coupling structures as long as the frame components 32 and 42 are coupled to each other with certainty.

Two frame components 32 and two frame components 42 having such shapes are located such that the same type of frame components face each other diagonally, and thus a rectangular-like frame shape is formed. The frame 30 is formed by coupling the coupling portions 38 and 48 at the ends of the frame components 32 and 42 and coupling the coupling portions 39 and 49 at the ends of the frame components 32 and 42. Owing to this, the frame 30 realizes a point symmetry with respect to a central point thereof.

Now, with reference to FIG. 5, the panel locating structure 50 formed on the front frame portion 33 in the frame corner portion 35 of the frame component 32 will be described.

As shown in FIG. 5, the panel locating structure 50 formed in the frame corner portion 35 of the frame component 32 includes a rib-like protrusion 52 protruding upward at a prescribed height from the front frame portion 33 and a clearance adjusting member 54 located adjacent to the protrusion 52. The protrusion 52 is formed (typically, integrally molded with the frame component 32) to have an L-shape as seen in a plan view so as to be along the frame corner portion 35 having a shape with a right angle. A portion of the front frame portion 33 which is inner to the protrusion 52 is an inner-side panel receiving portion 36 on which the peripheral portion (the rectangular-like peripheral portion mentioned above) of the liquid crystal panel 10 is to be located. In the frame 30, a rectangular area formed inside the protrusions 52 of the two frame components 32 located diagonally is a panel receiving area 30d on which the liquid crystal panel 10 is to be located. Preferably, the position of each protrusion 52 is set on the front frame portion 33 such that the panel receiving area 30d is slightly larger than the actual size of the liquid crystal panel 10.

Regarding the protrusion 52 having the L-shape as seen in a plan view, a portion thereof along the shorter side of the frame 30 is partially recessed from an inner periphery (toward an outer periphery) of the frame 30 to form a recessed portion 52a. Adjacent to the recessed portion 52a, the clearance adjusting member 54 is provided. The clearance adjusting member 54 is typically formed of an elastic material such as rubber, elastomer or the like and has a flat parallelepiped shape. In this embodiment, a side surface 55 of one of longer sides of the clearance adjusting member 54 having the parallelepiped shape is located (provided) to slightly extend toward the inner periphery from a portion of the protrusion 52 which is along the shorter side of the frame and excludes the recessed portion 52a. Namely, the above-mentioned portion of the clearance adjusting member 54 extends toward the inner-side panel receiving portion 36 by thickness W₁. It is preferable that the protrusion 52 includes the recessed portion 52a because the recessed portion 52a makes it easier to specify the position at which the clearance adjusting member 54 is to be provided, but the recessed portion 52a is not absolutely necessary. There is no specific limitation on the plane shape of the protrusion 52 as long as the clearance adjusting member 54 can be located to extend toward the inner-side panel receiving portion 36 from the protrusion 52.

When the liquid crystal panel 10 is located on the panel receiving area 30d of the frame 30 including the clearance adjusting member 54, one of the four corners of the liquid crystal panel 10 is on the inner-side panel receiving portion 36 so as to be along the generally L-shaped protrusion 52. In this state, the extending side surface 55 of the clearance adjusting member 54 for the liquid crystal panel 10 acts as a contact surface 55 contactable with a part of a corresponding side surface of the liquid crystal panel 10. The clearance adjusting member 54 merely needs to be provided adjacent to one of the protrusions 52 provided in the frame corner portions 35 of the two frame components 32 of the frame 30 located diagonally.

Preferably, when the liquid crystal panel 10 is located on the panel receiving area 30d while being in contact with the contact surface 55, the liquid crystal panel 10 is automatically at a correct position (typically, a position at which the center of the frame 30 and the center of the liquid crystal panel 10 match each other). Preferably, the thickness of the clearance adjusting member 54 in the extending direction (i.e., the length of the clearance adjusting member 54 in the direction of the shorter side of the parallelepiped shape) is adjusted (i.e., the position of the contact surface 55 is adjusted) so as to realize the state where the liquid crystal panel 10 is at the above-mentioned position. Owing to this, the clearance adjusting member 54 can act as a positioning member for the liquid crystal panel 10. In FIG. 5, reference character 56 represents an engageable portion, formed outer to the protrusion 52, for fixing the frame 30 and the bezel 20 located above the frame 30.

Now, with reference to FIG. 6, the panel locating structure 60 formed on the front frame portion 43 in the frame corner portion 45 of the frame component 42 will be described.

As shown in FIG. 6, the panel locating structure 60 formed in the frame corner portion 45 of the frame component 42 may have substantially the same structure as that of the panel locating structure 50. Namely, the panel locating structure 60 includes a rib-like protrusion 62 protruding upward at a prescribed height from the front frame portion 43 and a clearance adjusting member 64 located adjacent to the protrusion 62. The protrusion 62 is formed (typically, integrally molded with the frame component 42) to have an L-shape as seen in a plan view so as to be along the frame corner portion 45 having a shape with a right angle. A portion of the front frame portion 43 which is inner to the protrusion 62 is an inner-side panel receiving portion 46, like the inner-side panel receiving portion 36.

Regarding the protrusion 62 having the L-shape as seen in a plan view, a portion thereof along the shorter side of the frame 30 is partially recessed from the inner periphery (toward the outer periphery) of the frame 30 to form a recessed portion 62a, like the protrusion 52. Adjacent to the recessed portion 62a, the clearance adjusting member 64 is provided. The clearance adjusting member 64 is typically formed of an elastic material such as rubber, elastomer or the like and has a flat parallelepiped shape. In this embodiment, a side surface 65 of one of longer sides of the parallelepiped shape is located (provided) to slightly extend toward the inner periphery from a portion of the protrusion 62 which is along the shorter side of the frame and excludes the recessed portion 62a. Namely, the above-mentioned portion of the clearance adjusting member 64 extends toward the inner-side panel receiving portion 46 by thickness W₂. Like the clearance adjusting member 54, the clearance adjusting member 64 merely needs to be provided adjacent to one of the protrusions 62 provided in the frame corner portions 45 of the two frame components 42 of the frame 30 located diagonally. Note that, in the case where one clearance adjusting member 54 and one clearance adjusting member 64 are provided in the frame 30 formed of two frame components 32 and two frame components 42, it is preferable that, as shown in FIG. 3, FIG. 4 and FIG. 7 regarding this embodiment, the one clearance adjusting member 54 and the one clearance adjusting member 64 are provided to face each other in the direction of the longer side of the frame 30.

The clearance adjusting member 64 is different from the clearance adjusting member 54 in that the thickness W₂, in the extending direction, of the portion of the clearance adjusting member 64 extending toward the inner-side panel receiving portion 46 is smaller than the thickness W₁, in the extending direction, of the portion of the clearance adjusting member 54 extending toward the inner-side panel receiving portion 36. The thicknesses W₁ and W₂ can be made different from each other easily by forming the clearance adjusting member 54 to be thicker than the clearance adjusting member 64. For example, in this embodiment, the thickness W₁ of the clearance adjusting member 54 is 3.0 mm and the thickness W₂ of the clearance adjusting member 64 is 2.5 mm. Since the thickness W₂ of the clearance adjusting member 64 is smaller, when the liquid crystal panel 10 is located on the inner-side panel receiving portion 46, the contact surface 55 and the corresponding side surface of the liquid crystal panel 10 contact each other but the side surface 65 of the longer side and the corresponding side surface of the liquid crystal panel 10 have a slight gap 67 therebetween (see FIG. 8). It is preferable that the clearance adjusting member 64 is colored with a different color from the clearance adjusting member 54 or marked, so as to be visually distinguishable easily from the clearance adjusting member 54. In this embodiment, the clearance adjusting members 54 and 64 are colored with different colors from each other. In FIG. 6, reference character 66 represents an engageable portion, formed outer to the protrusion 62, for fixing the frame 30 and the bezel 20 located above the frame 30.

The liquid crystal panel 10 is located on the frame 30 having the above-described structure as follows, for example. As shown in FIG. 7, first, the liquid crystal panel 10 is located such that the panel 10 (rear surface thereof) faces the front portion 30a of the frame 30 and is above the panel receiving area 30d. Next, to the frame corner portion 35 (corner 30c of the frame 30) in which the panel locating structure 50 including the clearance adjusting member 54 which can act as a positioning member is formed, a corner 10b of the liquid crystal panel 10 corresponding to the frame corner portion 35 is moved closer. The liquid crystal panel 10 is located to incline with respect to the frame 30 such that the corner 10b contacts the corner of the generally L-shaped protrusion 52 in the frame corner portion 35 (more precisely, the corner or the internal corner of the inner-side panel receiving portion 36 in the state where the clearance adjusting member 54 is located). At this point, the corresponding side surface of the liquid crystal panel 10 is brought into contact with the contact surface 55 of the clearance adjusting member 54.

Next, the liquid crystal panel 10 is pressed in the inclining direction to slightly compress the clearance adjusting member 54, formed of an elastic material, via the contact surface 55. Then, while the liquid crystal panel 10 is pivoted using the contact portion between the clearance adjusting member 54 and the liquid crystal panel 10 (pressed portion) as the center of pivoting, a corner 10c of the liquid crystal panel 10 facing the corner 10b in the direction of the longer side is located to contact the protrusion 62 of the panel locating structure 60 including the clearance adjusting member 64.

As shown in FIG. 8, the panel locating structure 60 is structured such that the clearance adjusting member 64 and the corresponding side surface of the liquid crystal panel 10 have the gap 67 therebetween. Therefore, the gap 67 acts as a clearance, which allows the liquid crystal panel 10 to be easily located with respect to the frame 30. Since the clearance adjusting member 54 is formed of an elastic material, a sum of the compression and the gap 67 acts as a clearance, which makes it easier to locate the liquid crystal panel 10.

In the above-described manner, the liquid crystal panel 10 can be located on the frame 30 while being positioned correctly.

A method for producing the liquid crystal display device 100 in this embodiment may be the same as the conventional method, and there is no specific limitation on the method. One example of production method is as follows. After the liquid crystal panel 10 is located on the frame 30 while being positioned correctly as described above, the optical members 78 and the backlight device 70 accommodated in the case 74 are mounted on the rear side of the frame 30. On the front side of the liquid crystal panel 10, the bezel 20 is located. While the liquid crystal panel 10 is held between the frame 30 and the bezel 20, all of the liquid crystal panel 10, the frame 30 and the backlight device 70 are assembled. Thus, the liquid crystal display device 100 can be produced.

The present invention has been described so far by way of a preferable embodiment, but the above descriptions do not limit the present invention, and the present invention may be altered in many ways, needless to say. For example, in the above embodiment, the frame 30 is formed of two of two types of components 32 and 42, each of which is obtainable by dividing the frame 30 into four. For example, the frame may be formed of two generally C-shaped frame components, which are obtainable by dividing the frame into two.

In the above embodiment, the two clearance adjusting members 54 and 64 are colored with different colors from each other so as to be visually distinguishable. Instead of being colored, the clearance adjusting members 54 and 64 may be marked (e.g., “Right” is printed on one and “Left” is printed on the other).

In the above embodiment, a liquid crystal display device is described as a typical example of the display device. The present invention is applicable to various types of display devices including substantially the same panel locating structure.

### INDUSTRIAL APPLICABILITY

The present invention provides a preferable display device which allows a display panel to be located easily while positioning the display panel with respect to a frame efficiently and in a preferable manner.

### DESCRIPTION OF REFERENCE CHARACTERS

W₁, W₂ Thickness in the extending direction
10 Liquid crystal panel
10a Display area
11 Array substrate
12 Color filter (CF) substrate
13 Liquid crystal layer
20 Bezel
30 Frame
32 Frame component
36 Inner-side panel receiving portion
42 Frame component
46 Inner-side panel receiving portion
50 Panel locating structure
52 Protrusion
54 Clearance adjusting member
60 Panel locating structure
62 Protrusion
64 Clearance adjusting member
70 Backlight device
100 Liquid crystal display device

1. A display device, comprising:
a display panel having a rectangular shape;
a frame of a frame-like shape located on a rear side of the display panel; and
a bezel of a frame-like shape located on a front side of the display panel;
wherein:
the panel is held between the frame and the bezel;
a surface of the frame facing the panel has an inner-side panel receiving portion on which at least a part of a peripheral portion of the panel is located, and a protrusion formed outer to the inner-side panel receiving portion;
among a plurality of sides forming the frame, either one pair of sides facing each other each have the protrusion formed thereon and a clearance adjusting member, for adjusting a clearance between the protrusion and the display panel located on the inner-side panel receiving portion, provided as at least partially extending toward the inner-side panel receiving portion; and
the clearance adjusting members of the one pair of sides are shaped differently from each other such that an extending portion, extending toward the inner-side panel receiving portion, of the clearance adjusting member provided on one of the one pair of sides, and an extending portion, extending toward the inner-side panel receiving portion, of the clearance adjusting member provided on the other of the one pair of sides, have different thicknesses from each other in respective extending directions thereof.

2. The display device of claim 1, wherein the clearance adjusting member provided on one of the one pair of sides is formed to be thicker than the clearance adjusting member provided on the other of the one pair of sides.

3. The display device of claim 1, wherein among the clearance adjusting member provided on one of the one pair of sides and the clearance adjusting member provided on the other of the one pair of sides which have different thicknesses from each other, at least one clearance adjusting member is colored or marked so that the clearance adjusting members are visually distinguishable from each other.

4. The display device of claim 1, wherein the clearance adjusting members are formed of an elastic material.

5. The display device of claim 1, wherein:
the frame is formed of a plurality of frame components connected to each other; and
the plurality of frame components are shaped such that the frame formed of the plurality of frame components connected to each other realizes a point symmetry with respect to a central point thereof.

6. A frame of a frame-like shape for a display device including a display panel having a rectangular shape, the frame being located on a rear side of the display panel; wherein:
a surface of the frame which is to face the panel when the display device is constructed has an inner-side panel receiving portion on which at least a part of a peripheral portion of the panel is to be located, and a protrusion formed outer to the inner-side panel receiving portion;
among a plurality of sides forming the frame, either one pair of sides facing each other each have the protrusion formed thereon and a clearance adjusting member, for adjusting a clearance between the protrusion and the display panel to be located on the inner-side panel receiving portion, provided as at least partially extending toward the inner-side panel receiving portion; and
the clearance adjusting members of the one pair of sides are shaped differently from each other such that an extending portion, extending toward the inner-side panel receiving portion, of the clearance adjusting member provided on one of the one pair of sides, and an extending portion, extending toward the inner-side panel receiving portion, of the clearance adjusting member provided on the other of the one pair of sides, have different thicknesses from each other in respective extending directions thereof.

7. The frame of claim 6, wherein the clearance adjusting member provided on one of the one pair of sides is formed to be thicker than the clearance adjusting member provided on the other of the one pair of sides.

8. The frame of claim 6, wherein among the clearance adjusting member provided on one of the one pair of sides and the clearance adjusting member provided on the other of the one pair of sides which have different thicknesses from each other, at least one clearance adjusting member is colored or marked so that the clearance adjusting members are visually distinguishable from each other.

9. The frame of claim 6, wherein the clearance adjusting members are formed of an elastic material.

10. The frame of claim 6, wherein:
the frame is formed of a plurality of frame components connected to each other; and
the plurality of frame components are shaped such that the frame formed of the plurality of frame components connected to each other realizes a point symmetry with respect to a central point thereof.
